(19) United States
(12) Patent Application Publication
(10) Pub. No.: US 2026/0011572 A1
(43) Pub. Date: Jan. 8, 2026

(54) Low Temperature Plasma Enhanced Processing for Microelectronics Manufacturing

(71) Applicant: MicroSol Technologies Inc., Plano, TX (US)

(72) Inventors: Yuanning Chen, Plano, TX (US); Harvey Stiegler, Plano, TX (US); Yafen Tian, Milpitas, CA (US)

(21) Appl. No.: 19/238,491

(22) Filed: Jun. 15, 2025

Related U.S. Application Data
(60) Provisional application No. 63/668,154, filed on Jul. 5, 2024.

(51) Int. Cl. H01L 21/324

(52) U.S. Cl. CPC H01L 21/324

(57) ABSTRACT

A Plasma Enhanced Anneal (PEA) includes a exposing a top surface region of a substrate to a plasma to reduce the required activation energy temperature to anneal dopants for microelectronic devices. The plasma in a PEA process bombards surfaces with ions and atoms created in the plasma which allows controllable kinetic energy and ion flux to be transferred to the top surface region of the substrate and activate dopants at temperatures as low as 300° C. The plasma energy of the ions is known to dissipate into a region only a few nanometers in depth with energy densities large enough to activate dopants. PEA processing may be a promising method for dopant activation at temperatures lower than thermal techniques alone. PEA processing may also result in reduced thermal budget necessary for form silicides, anneal silicides, and anneal high-k dielectric materials.

### CROSS-REFERENCE TO RELATED APPLICATIONS

This application claims the benefit of priority under 35 U.S.C. § 119 (e) of U.S. Provisional Application No. 63/668,154 (Microsol docket number QMR002P), filed Jul. 5, 2024, which is hereby incorporated by reference in its entirety.

### TECHNICAL FIELD

This disclosure relates to the field of semiconductor devices. More particularly, but not exclusively, this disclosure relates to annealing and activating dopants, forming and annealing silicides, and annealing high-k dielectric materials in microelectronic devices.

### BACKGROUND

Annealing and activation of dopants are important in semiconductor manufacturing. Sensitive architectures require activation with very low diffusion. Methods to effectively anneal and activate dopants with a low thermal budget are challenging. Forming metal silicides and annealing high-k dielectric materials with low thermal budgets are also challenging.

### SUMMARY

This summary is provided to introduce a brief overview of disclosed concepts in a simplified form that are further described below in the detailed description including the drawings provided. This summary is not intended to limit the scope of the disclosure or the claims.

Disclosed examples include microelectronic devices, e.g., integrated circuits and methods of making such devices. Examples include processing steps which includes a plasma enhanced anneal (PEA) process which may lower the thermal budget of an anneal process. Examples include annealing and activation of dopants, formation and annealing of silicides, and annealing of high-k dielectric materials.

Activating dopants with reduced diffusion at lower temperatures is challenge in semiconductor manufacturing for sensitive architectures. A PEA process includes exposing a top surface region of a substrate to a plasma to reduce the required activation energy temperature to anneal dopants for microelectronic devices. The plasma in a PEA process bombards surfaces with ions and atoms created in the plasma which allows controllable kinetic energy and ion flux to be transferred to the wafer surface to activate dopants. The plasma energy of the ions is known to dissipate into a region only a few nanometers in depth with energy densities large enough to activate dopants. PEA processing may be a promising method for dopant activation at temperatures lower than thermal techniques alone. PEA processing may also result in reduced thermal budget necessary for form silicides, anneal silicides, and anneal high-k dielectric materials.

### BRIEF DESCRIPTION OF THE FIGURES

FIG. 1 is a cross section of a plasma enhanced annealing chamber.

FIG. 2 is a cross section of plasma enhanced annealing chamber including a thermal source.

FIG. 3 is a cross section of a plasma enhanced annealing chamber including

a microwave source.

FIG. 4 is a process flow diagram for a plasma enhanced annealing process.

FIG. 5 is a process flow diagram for a plasma enhanced annealing process including a microwave source.

FIG. 6 is a graph comparing the sheet resistance of a substrate after processing in a plasma enhanced anneal process compared to a substrate processed with a thermal anneal process and a substrate processed with a rapid thermal anneal (RTA) process.

### DETAILED DESCRIPTION

The present disclosure is described with reference to the attached figures. The figures are not drawn to scale and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

In addition, although some of the examples illustrated herein are shown in two dimensional views with various regions having depth and width, it should be clearly understood that these regions are illustrations of only a portion of a device that is actually a three-dimensional structure. Accordingly, these regions will have three dimensions, including length, width, and depth, when fabricated on an actual device. Moreover, while the present disclosure may be illustrated by examples directed to active devices, it is not intended that these illustrations be a limitation on the scope or applicability of the present disclosure. It is not intended that the active devices of the present disclosure be limited to the physical structures illustrated. These structures are included to demonstrate the utility and application of the present disclosure to various examples.

It is noted that terms such as top, over, and above may be used in this disclosure. These terms should not be construed as limiting the position or orientation of a structure or element, but should be used to provide spatial relationship between structures or elements.

A major technical challenge for advanced semiconductor technologies is dopant activation at lower temperatures for microelectronic devices with sensitive architectures which require dopant activation with very low dopant diffusion. Typical dopants may be elements such as arsenic, boron, phosphorous, antimony, selenium, tellurium, gallium, indium, or aluminum. Other elements which may be used as dopants are within the scope of the disclosure. For advanced CMOS technologies, in order to minimize both junction and channel resistances it is essential to anneal and electrically activate implanted dopants, repair lattice damage from ion implantation, and control dopant diffusion at temperatures low enough maintaining the shallow junction requirements. Similar low temperature annealing requirements may be advantageous in micro-electromechanical systems (MEMS) devices.

Plasma Enhanced Annealing (PEA) is a method which may effectively activate and anneal dopants at temperatures at or below 300° C. using radio frequency (RF) power to produce a plasma from a working gas at pressures between 0.1 millitorr and 200 torr and exposing the top surface region of a substrate to the plasma. The working gas includes a gas selected from the group consisting of helium, non, argon, krypton, and xenon, (the noble gases). The working gas may also include an inert gas such as nitrogen. Hydrogen gas may also be added to the working gas to enhance the ion density of the plasma which may enhance PEA process at lower temperatures than a working gas lacking hydrogen gas. The plasma generated from the working gas contains a controllable number of working gas ions and electrons along with working gas atoms. A semiconductor substrate herein referred to as a substrate may be biased at a negative potential to induce the working gas ions of the plasma to impact the semiconducting substrate surface with a controlled ion energy.

In a PEA process, ions from the working gas plasma collide with the substrate surface. For the purposes of the disclosure, the top surface region refers to the top surface of the substrate and the region within 20 nm of the top surface. During the ion bombardment of a top surface region of the substrate, some of the momentum of the bombarding ions is transferred to the surface layer atoms of the top surface region leading to enhanced surface mobility of atoms in the surface layers of the top surface region and healing defects in the surface layers such as interstitial dislocations and non-crystalline chain defects as well as activating dopants in the surface layers by allowing them to move from interstitial space to substitutional locations in the substrate crystal lattice. By careful choice of process parameters, the characteristics of the bombarding ions of the plasma may be controlled to allow precise control of the annealing rate, surface uniformity and crystallinity of the surface layers of the top surface region. To determine the ion density of the plasma, current density-voltage (J-V) curves via Langmuir probe theory with a DC substrate bias may be used. The J-V curves may be used to calculate the ion saturation current (Iᵢₒₙ), floating potential (V_{f}), and electron temperature (Te).

Mixtures of noble gases as the working gas may enhance the effects of the PEA more than a single noble gas alone and allow an overall lower thermal budget of the PEA process. A working gas using a mixture of helium and argon may result in a plasma which may result in less plasma damage to the substrate during the PEA process than a working gas using argon alone due to the smaller atomic mass of He and increased Ar ionization via the penning effect in which the metastable He* provides a mechanism to generate additional argon ions. The addition of helium to an argon plasma may result in improved crystalline characteristics of the substrate at a given momentum of plasma ions with lower applied substrate bias and lower overall power budget. This results in the ability to activate and anneal the substrate at lower temperatures than through thermal heating alone which results in less movement of the species to be annealed. Current-voltage (IV) curves of the low temperature PEA at 300° C. show comparable diode characteristics to a substrate annealed using a 800° C. using a rapid thermal anneal (RTA) while a substrate using a thermal anneal at 300° C. does not undergo sufficient activation to form a diode.

Silicide layers may also be formed using a PEA process. Titanium silicide, cobalt silicide, and nickel silicide are widely used in the formation of ohmic contact between a semiconductor substrate and contacts to the metallization layers in microelectronic devices. Elements which are used to form silicide layers in semiconductor processing may include titanium, cobalt, nickel, tungsten, manganese, iron, copper, vanadium, zirconium, hafnium, and thorium. Other metals which form silicide layers are within the scope of the disclosure. In a silicide layer formation process, a metal layer is deposited on a substrate and then a thermal process is used to facilitate a solid state reaction between the metal layer and underlying silicon to form the silicide layer. Following the silicide layer formation process, and chemical stripping process is used to remove unreacted metal. A silicide anneal process may be used to complete the silicide process. A PEA may allow formation of silicide layers at lower temperature, and formation of silicide layers at thinner thicknesses than through thermal means alone which is advantageous to reduce the consumption of the underlying substrate. The lower temperature of formation of a silicide PEA anneal may also reduce undesired side reactions such as nickel silicide spiking into the substrate.

High-k dielectric layers may also be annealed using a PEA process. A PEA may allow annealing of high-k dielectric layers at lower temperatures and thus anneal the high-k dielectric layer with less thermal budget to the underlying substrate, and less thermal budget to a polysilicon or metal gate material if present. High-k dielectric layers which may be annealed using a PEA process may include SiₓO_{y}, SiₓN_{y}, HfOₓ, HfₓSiO_{y}, ZrOₓ, ZrₓSiO_{y}, LaₓGdO_{y}, SiOₓ, SiNₓ, SiOₓ N_{y}, and TaOₓ. Other high-k dielectric layers are within the scope of the disclosure.

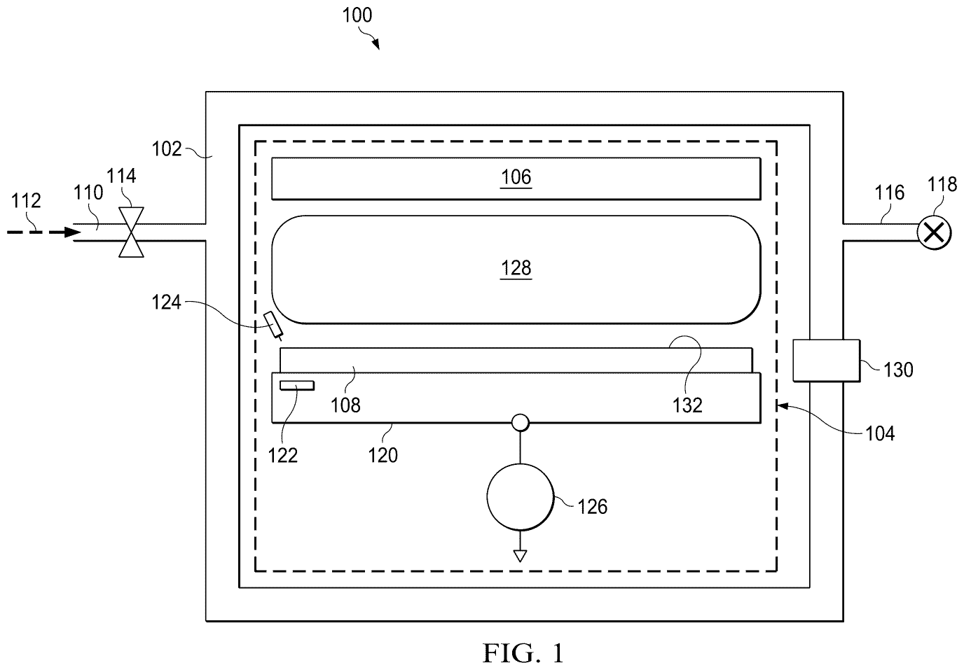

FIG. 1 is a schematic cross section of a first type of PEA reaction chamber 100 which may allow low temperature annealing. The PEA reaction chamber 100 consists of a containment chamber 102, which may hold a vacuum and which may isolate a PEA reaction region 104 from the ambient environment. The containment chamber 102 may contain heating elements (not specifically shown) which may provide a constant temperature to the PEA reaction region 104 within the containment chamber 102. A plasma source 106 in the PEA reaction region 104 may be above a semiconductor substrate 108, herein referred to as a substrate 108 with a top surface region 132. The substrate 108 may be silicon or other material suitable for forming microelectronic devices. Introducing a working gas 112 to the containment chamber 102 is done through a gas inlet port 110 connected to the containment chamber 102 which allows the introduction of the working gas 112 through a gas inlet valve 114. A gas outlet port 116 may be connected to the containment chamber 102 as an exhaust for the working gas 112. An opposite end of the gas outlet port 116 may be connected to a vacuum source 118. The gas inlet valve 114 and vacuum source 118 allow a controlled pressure of the working gas 112 within the PEA reaction region 104. The substrate 108 may be on a wafer chuck 120. The substrate 108 is in contact with the wafer chuck 120. The wafer chuck 120 may have a thermocouple 122 for monitoring the temperature of the substrate 108, and a pyrometer 124 may be above the substrate 108 to measure the surface temperature of the substrate 108. The pyrometer 124 may be used to monitor the temperature of the top surface region 132 of the substrate 108. The wafer chuck 120 may contact RF and direct current (DC) sources 126 which allow RF and DC biasing of the substrate 108. The wafer chuck 120 and plasma source 106 may enable a plasma 128 to be formed which contacts and may be uniform over the top surface region 132 of the substrate 108. A wafer handling port 130 allows insertion and extraction of the substrate 108.

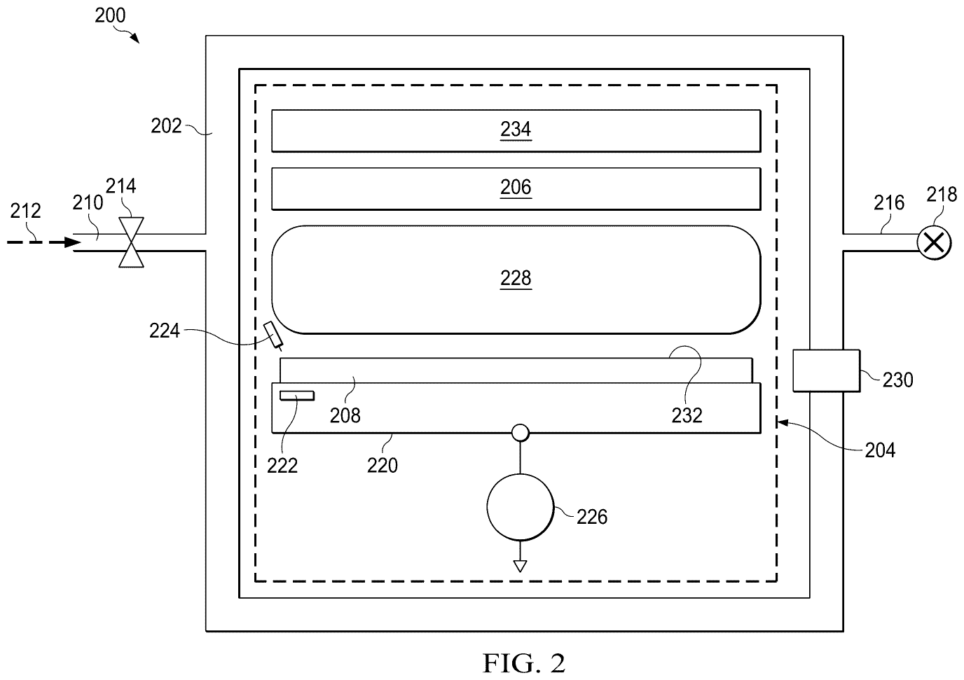

FIG. 2 is a schematic cross section of a second type PEA reaction chamber 200 which may allow low temperature annealing. The PEA reaction chamber 200 consists of a containment chamber 202, which may hold a vacuum and which may isolate a PEA reaction region 204 from the ambient environment. The containment chamber 202 may contain heating elements (not specifically shown) which may provide a constant temperature to the PEA reaction region 204 within the containment chamber 202. A plasma source 206 in the PEA reaction region 204 may be above a semiconductor substrate 208 herein referred to as a substrate 208 with a top surface region 232. The substrate 208 may be silicon or other material suitable for forming microelectronic devices. Introducing a working gas 212 through a gas inlet port 210 connected to the containment chamber 202 allows the introduction of the working gas 212 through a gas inlet valve 214. A gas outlet port 216 may be connected to the containment chamber 202 as an exhaust for the working gas 212. An opposite end of the gas outlet port 216 may be connected to a vacuum source 218. The gas inlet valve 214 and vacuum source 218 allow a controlled pressure of the working gas 212 within the PEA reaction region 204. The substrate 208 may be on a wafer chuck 220. The substrate 208 is in contact with the wafer chuck 220. The wafer chuck 120 may have a thermocouple 222 for monitoring the temperature of the substrate 208, and a pyrometer 224 may be above the substrate 208 to measure the surface temperature of the substrate 208. The pyrometer 224 may be used to monitor the temperature of the top surface region 232 of the substrate 208. The wafer chuck 220 may contact RF and DC sources 226 which allow RF and DC biasing of the substrate 208. A thermal source 234, examples of which include resistive heating, lamps, lasers, or ultraviolet radiation may also be above the substrate 208, the thermal source 234 may provide additional thermal budget to the substrate 208. The wafer chuck 220 and plasma source 206 may enable a plasma 228 to be formed which contacts and may be uniform over the top surface region 232 of the substrate 208. A wafer handling port 230 allows insertion and extraction of the substrate 208.

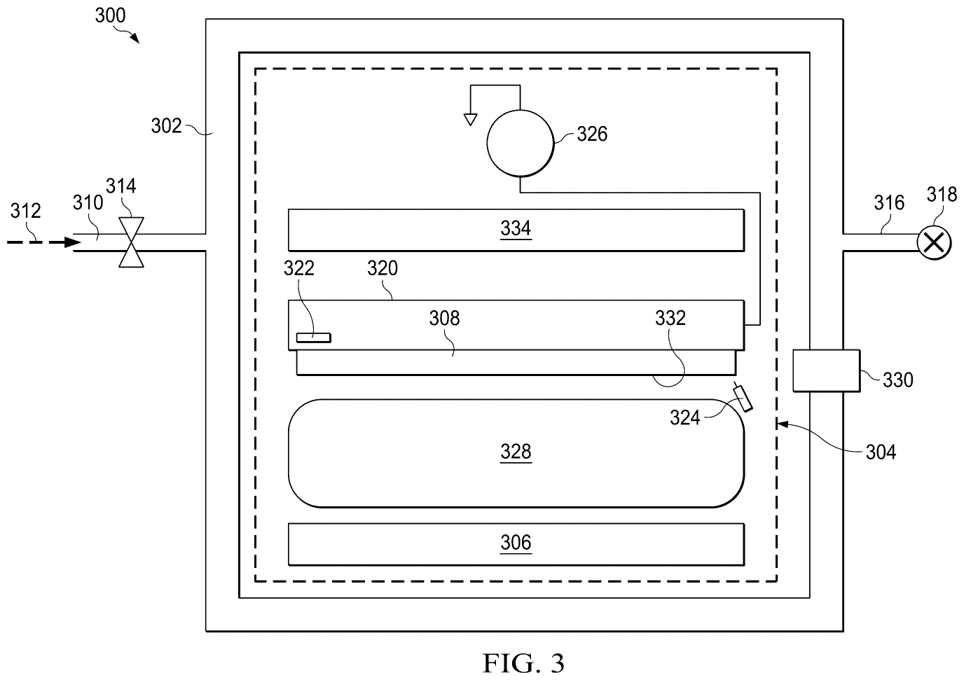

FIG. 3 is a schematic cross section of a third type of PEA reaction chamber 300 which may allow low temperature annealing. The configuration of the PEA reaction chamber 300 shown in FIG. 3 includes a microwave source 334. A microwave source 334 may be advantageous in a PEA process as a means to heat a semiconductor substrate 308 herein referred to as a substrate 308 with rapidly alternating electric fields of the microwaves which may selectively heat dopant ions more than substrate atoms in the substrate 308. The microwaves of the microwave source 334 also offer rapid heating rates and sharp temperature gradients within the substrate 308. Both of the preceding properties of a microwave source 334 may be beneficial to enhance a PEA process and aid in minimizing dopant diffusion while maximizing dopant activation near a top surface region 332 of the substrate 308.

The PEA reaction chamber 300 consists of a containment chamber 302, which may hold a vacuum and which may isolate a PEA reaction region 304 from the ambient environment. The containment chamber 302 may contain heating elements (not specifically shown) which may provide a constant temperature to the PEA reaction region 304 within the containment chamber 302. A plasma source 306 in the PEA reaction region 304 may be below the substrate 308. The substrate 308 may be silicon or other material suitable for forming microelectronic devices. Introducing a working gas 312 through a gas inlet port 310 connected to the containment chamber 302 allows the introduction of the working gas 312 through a gas inlet valve 314. An end of a gas outlet port 316 may be connected to the containment chamber 302. An opposite end of the gas outlet port 316 may be connected to a vacuum source 318. The gas inlet valve 314 and vacuum source 318 allow a controlled pressure of the working gas 312 within the PEA reaction region 304. The substrate 308 may be on a wafer chuck 320. The substrate 308 is in contact with the wafer chuck 320. The wafer chuck 320 may have a thermocouple 322 for monitoring the temperature of the wafer chuck 220 and the substrate 308, and a pyrometer 324 may be below the substrate 308. The pyrometer 324 may be used to monitor the temperature of the top surface region 332 of the substrate 308. The wafer chuck 320 may be connected to an RF and DC generator 326 which may provide RF and DC bias to the wafer chuck 320 and the substrate 308. The wafer chuck 320 and plasma source 306 may enable a plasma 328 to be formed which contacts and may be uniform over the top surface region 332 of the substrate 308. A wafer handling port 330 allows insertion and extraction of the substrate 308. For the microwave source 334, a power of between 0.7 GHZ and 100 GHz with a power between 20 Watts and 3000 Watts may be used. While the configuration in FIG. 3 shows a substrate 308 in an inverted configuration with a plasma 328 below the substrate 308, a configuration similar to FIG. 1 in which the substrate 108 is on a wafer chuck 120 with a plasma 128 above the substrate 108 is within the scope of the disclosure.

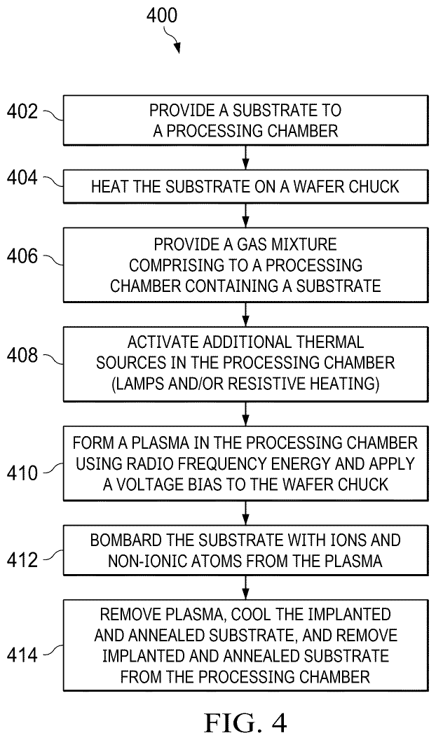

FIG. 4 presents a method 400 of an example PEA annealing process. Structural elements referred to in the steps of the method 400 are shown in FIG. 1 or FIG. 2.

In step 402, the substrate 108 may be provided through the wafer handling port 130 into the containment chamber 102 of the PEA reaction chamber 100 and placed on the wafer chuck 120 within the containment chamber 102. The containment chamber 102 of the PEA reaction chamber 100 may be at a constant temperature, (180° C. to 240° C. by way of example). Before being placed in the PEA reaction chamber 100, the substrate 108 may be provided after being implanted with a dopant such as arsenic with a dose of 1×10¹⁴ cm⁻² at 10 keV, boron in the form of BF₂ with a dose of 1×10¹⁴ cm⁻² at 5 keV, or phosphorus with a dose of 5×10¹⁵ cm⁻² at 60 keV by way of example.

For a PEA silicide formation process, the substrate 108 may be provided after the top surface region 132 is coated with a layer of a metal (5 nm to 50 nm by way of example) such as titanium, cobalt or nickel and optionally covered by a capping layer of titanium or titanium nitride (50 nm to 250 nm by way of example).

For a PEA silicide anneal, the substrate 108 may be provided after a silicide formation and silicide strip process.

For a PEA high-k dielectric anneal, the substrate 108 may be provided after a high-k dielectric layer deposition on the top surface region 132 or after a high-k dielectric layer deposition and metal gate or polysilicon gate integration process.

In step 404, the substrate 108 is allowed to come to an equilibrium temperature on the wafer chuck 120. The wafer chuck 120 may be heated to a constant temperature (180° C. and 240° C., by way of example) by the ambient temperature of the containment chamber 102, or the wafer chuck 120 may contain an active heating element.

In step 406, the working gas 112 may be added through the gas inlet port 110 and controlled by the gas inlet valve 114 resulting in a flow rate of between 5 standard cubic centimeters per minute (sccm) and 100 sccm. By varying the gas inlet valve 114 position and a vacuum source 118, control of the working gas 112 pressure may be maintained between 0.1 millitorr to 200 torr by way of example within the PEA reaction region 104.

The working gas 112 may be a single noble gas such as helium, neon, argon, krypton, or xenon. The working gas 112 may also be a mixture of a noble gas in combination with an inert gas such as nitrogen gas. The working gas 112 may also be a mixture consisting of a combination of a noble gas and hydrogen gas. A working gas 112 consisting of a mixture of a noble gas, other than helium, and helium may also be used.

In step 408, (which may be an optional step) a thermal source 234, may be used to provide additional thermal budget to the PEA process. Examples of the thermal source 234 may be at least one of resistive heating, lamps, lasers, or ultraviolet radiation. For a dopant anneal and activation PEA, the thermal source 234 may provide additional heating such that the temperature of the top surface region 232 of the substrate 208 may be between of between 200° C. and 500° C., by way of example, which may in combination with the plasma 228 which is discussed in step 410 provide the required activation energy for a annealing and activation of the dopants in the top surface region 232 of the substrate 208.

For a cobalt silicide formation PEA, the thermal source may provide additional heating such that the temperature of the top surface region 232 of the substrate 208 may be between of between 200° C. and 600° C. by way of example which may in combination with the plasma 128 which is discussed in step 410 provide the required activation energy for a solid state reaction in which cobalt and the silicon in the substrate 108 undergo a chemical transformation to form cobalt silicide.

For a silicide formation PEA of a metal layer containing nickel, the thermal source may provide additional heating such that the temperature of the top surface region 232 of the substrate 208 may be between of between 100° C. and 250° C. by way of example which may in combination with the plasma 228 which is discussed in step 410 provide the required activation energy for a solid state reaction in which nickel and the silicon in the substrate 208 to undergo a chemical transformation to form nickel silicide.

For a high-k dielectric PEA, the thermal source may provide additional heating such that the temperature of the top surface region 232 of the substrate 208 may be between of between 200° C. and 400° C. by way of example which may in combination with the plasma 228 which is discussed in step 410 provide the required activation energy to anneal and recrystallize the high-k dielectric layer on the substrate 208.

In step 410, for a dopant activation and anneal PEA, a silicide formation PEA, a silicide anneal PEA, or a high-k dielectric layer PEA, an RF bias power of between 5 Watts and 5000 Watts (power density of 0.015 watts/cm² and 15.5 watts/cm²) and an RF voltage bias ranging between 5 Volts and 500 Volts may be applied in the PEA reaction region 104 to form a plasma 128, which may provide sufficient energy to anneal and activate dopants in the top surface region 132 of the substrate 108, or form silicides, anneal silicides, or anneal high-k dielectric materials on the top surface region 132 of the substrate 108. The addition of a plasma 128 to the heating provided by the wafer chuck 120 and the optional thermal heat source 234 may advantageously dramatically drop the temperature necessary to activate and anneal dopants in the top surface region 132 of the substrate 108, or form silicides, anneal silicides, or anneal high-k dielectric materials on the top surface region 132 of the substrate 108.

In step 412, during the PEA dopant activation and annealing process, the dopants in the substrate 108 are activated at the top surface region 132 of the substrate 108 by the bombarding of the top surface region 132 of the substrate 108 with ions and non-ionic atoms of the plasma. PEA processing is advantageous for dopant activation as exposing the top surface region 132 with plasma which bombards the top surface region 132 with ions and atoms provide a significant activation in the top 25 nm to 50 nm of the substrate 108 which significantly reduces diffusion of dopant species within the crystal lattice near the top surface region 132 which is advantageous in applications such as advanced CMOS with very shallow junctions. As implanted, the activation of dopants may be less than 10 percent. The PEA process may increase the dopant activation to greater than 50 percent or more.

The anneal time may be between 15 seconds and 1800 seconds. During the PEA process, ions from the plasma 128 collide with the top surface region 132 of the substrate 108. During the ion bombardment of the top surface region 132, some of the momentum of the bombarding ions is transferred to the surface atoms of the substrate 108, leading to enhanced surface mobility of atoms in the surface layers of the substrate 108 and healing of defects such as interstitial dislocations and non-crystalline chain defects and activating the dopants. For example, a PEA process at 300° C. may reduce the sheet resistance of an arsenic doped wafer (arsenic with a dose of 1×10¹⁴ cm⁻² at 10 keV) from over 500 ohms/sq to less than 10 ohms/sq indicating activation of the arsenic dopant.

Variation of working gas 112 stoichiometry, RF bias power, RF bias voltage, and optional heating by the thermal source 234 may impact the characteristics of the bombarding ions of the plasma and may allow precise control of the annealing rate, surface uniformity and crystallinity of the surface layers of the substrate 108. To determine the ion density, J-V curves via Langmuir probe theory with a DC substrate bias may be used. The J-V curves may be used to calculate the ion saturation current (Iᵢₒₙ), floating potential (V_{f}), and electron temperature (Te).

The addition of hydrogen to a noble gas such as argon as the working gas 112 may enhance the ion density of the plasma 128 and lead to an enhanced PEA process at lower temperatures than a noble gas alone as the working gas 112. A working gas 112 that includes primarily a noble gas, such as argon, and helium may result in a plasma 128 with less plasma damage to the substrate 108 due to the smaller atomic mass of He and increased argon ionization via the penning effect in which the metastable He* provides a mechanism to generate additional argon ions. The addition of helium to the plasma 128 may result in improved crystalline characteristics at a given momentum of plasma ions with lower applied substrate bias and lower overall power budget. This results in the ability to activate and anneal the substrate 108 at lower temperatures than through thermal heating alone may results in less movement of the species to be annealed. IV curves of the low temperature PEA at 300° C. show comparable diode characteristics to a substrate annealed using a 800° C. RTA while a substrate using a thermal anneal at 300° C. does not undergo sufficient activation to form a diode.

During a PEA silicide formation process, the metal layer on the substrate 108 is bombarded with ions and non-ionic atoms of the plasma. The silicide formation time may be between 15 seconds and 1800 seconds. During the ion bombardment of the metal layer on the substrate 108, some of the momentum of the bombarding ions is transferred to the surface atoms of the metal layer on the substrate 108, which imparts enough activation energy for a solid state reaction in which the metal layer on the top surface region 132 of the substrate 108 and the silicon in top surface region 132 of the substrate 108 undergo a chemical transformation to form a metal silicide layer. A cobalt silicide may be formed using a PEA process with a top surface region 132 of at a temperature between 200° C. and 600° C. A silicide containing nickel may be formed using a PEA process with a top surface region 132 at a temperature of between 100° C. and 250° C.

Variation of working gas 112 stoichiometry, RF bias power, RF bias voltage, and optional heating by the thermal source 234 may impact the characteristics of the bombarding ions of the plasma which may allow precise control of the silicide formation rate and silicide thickness. The addition of hydrogen to a noble gas such as argon as the working gas 112 may enhance the ion density of the plasma 128 and lead to an enhanced PEA process at lower temperatures than a noble gas alone as the working gas 112. The addition of helium to a working gas 112 of a noble gas such as argon to form the plasma 128 may result in less plasma damage to the substrate 108 due to the smaller atomic mass of helium and increased argon ionization via the penning effect in which the metastable He* provides a mechanism to generate additional argon ions.

During a PEA silicide layer anneal process, the silicide layer on the top surface region 132 of the substrate 108 is bombarded with ions and non-ionic atoms of the plasma. The silicide layer anneal time may be between 15 seconds and 1800 seconds. During the ion bombardment of the silicide on the substrate 108, some of the momentum of the bombarding ions is transferred to the surface atoms of the silicide on the substrate 108, which imparts enough activation energy for a solid state reaction within the silicide layer and between the silicide layer and the top surface region 132 of the substrate 108 which may result in improved crystallinity, improved diffusion of substrate atoms into the silicide, grain growth, improved silicide morphology and stress relaxation. A cobalt silicide may be annealed using a PEA process at a temperature of between 300° C. and 700° C. A silicide containing nickel may be annealed using a PEA process at a temperature of between 200° C. and 400° C.

Variation of working gas 112 stoichiometry, RF bias power, RF bias voltage, and optional heating by the thermal source 234 may impact the characteristics of the bombarding ions of the plasma which may allow precise control of the silicide anneal and resulting silicide layer characteristics. The addition of hydrogen to a noble gas such as argon as the working gas 112 may enhance the ion density of the plasma 128 and lead to an enhanced PEA process at lower temperatures than a noble gas alone as the working gas 112. The addition of helium to a working gas 112 of a noble gas such as argon to form the plasma 128 may result in less plasma damage to the substrate 108 due to the smaller atomic mass of helium and increased argon ionization via the penning effect in which the metastable He* provides a mechanism to generate additional argon ions.

During a PEA high-k dielectric layer anneal process, the high-k dielectric layer on the top surface region 132 of the substrate 108 is bombarded with ions and non-ionic atoms of the plasma. The high-k dielectric layer anneal time may be between 15 seconds and 1800 seconds. During the ion bombardment of the high-k dielectric layer on the substrate 108, some of the momentum of the bombarding ions is transferred to the surface atoms of the high-k dielectric layer on the substrate 108, which imparts enough activation energy to anneal the high-k dielectric layer which may result structural densification in which volatile residue and impurities from high-k dielectric layer precursors may be driven out of the high-k dielectric layer, oxygen vacancies may be reduced, reordering and densification may occur, defect passivation may be improved, stoichiometry may be improved, and mechanical stress relief may occur between the high-k dielectric layer and the top surface region 132 of the substrate 108.

Variation of working gas 112 stoichiometry, RF bias power, RF bias voltage, and optional heating by the thermal source 234 may impact the characteristics of the bombarding ions of the plasma which may allow precise control of the high-k dielectric layer anneal and resulting high-k dielectric layer characteristics. The addition of hydrogen to a noble gas such as argon as the working gas 112 may enhance the ion density of the plasma 128 and lead to an enhanced PEA process at lower temperatures than a noble gas alone as the working gas 112. The addition of helium to a working gas 112 of a noble gas such as argon may form the plasma 128 which may result in less plasma damage to the substrate 108 due to the smaller atomic mass of helium and increased argon ionization via the penning effect in which the metastable He* provides a mechanism to generate additional argon ions.

In step 414, after the PEA process is complete, the plasma 128 is removed, the substrate 108 is allowed to cool, and the substrate 108 after the PEA process is removed from the containment chamber 102 via the wafer handling port 130.

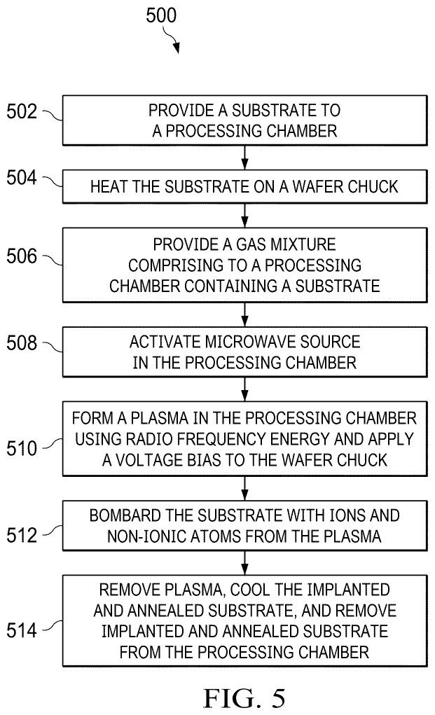

FIG. 5 presents a flowchart of an example method 500 for low temperature annealing a substrate 308 in a PEA reaction chamber 300 with a microwave source 334 in a configuration similar to the one shown in FIG. 3. Structural elements referred to in the steps of the method 500 are shown in FIG. 3.

In step 502, the substrate 308 may be provided through the wafer handling port 330 into the containment chamber 302 of the PEA reaction chamber 300 and placed on the wafer chuck 320 within the containment chamber 302. The containment chamber 302 of the PEA reaction chamber 300 may be at a constant temperature, (180° C. to 240° C. by way of example).

For a PEA dopant activation process, before being placed in the PEA reaction chamber 300, the substrate 308 may be implanted with a dopant such as arsenic with a dose of 1×10¹⁴ cm⁻² at 10 keV, boron in the form of BF₂ with a dose of 1×10¹⁴ cm⁻² at 5 keV, or phosphorus with a dose of 5×10¹⁵ cm⁻² at 60 keV by way of example.

For a PEA silicide layer formation process, before being placed in the PEA reaction chamber 300, the substrate 308 may be provided after a metal layer (5 nm to 50 nm by way of example) is formed on the top surface region 332, the metal layer being one such as titanium, cobalt, or nickel by way of example and optionally covered by a capping layer of titanium or titanium nitride (50 nm to 250 nm by way of example).

For a PEA silicide layer anneal process, before being placed in the PEA reaction chamber 300, the substrate 308 may be provided after a silicide formation and silicide strip process.

For a PEA high-k dielectric layer anneal, before being placed in the PEA reaction chamber 300, the substrate 308 may be provided after a high-k dielectric layer has been formed on the top surface region 332 of the substrate 308 or after the formation of the high-k dielectric layer and metal gate or polysilicon gate process.

In step 504, the substrate 308 is allowed to come to an equilibrium temperature on the wafer chuck 320. The wafer chuck 320 may be heated to a constant temperature (180° C. and 240° C. by way of example) by the ambient temperature of the containment chamber 302, or the wafer chuck 320 may contain an active heating element.

In step 506, the working gas 312 may be added through the gas inlet port 310 and controlled by the gas inlet valve 314 resulting in a flow rate of between 5 sccm and 100 sccm. By varying the gas inlet valve 314 position and a vacuum source 318, control of the working gas 312 pressure may be maintained between 0.1 millitorr to 200 torr by way of example within the PEA reaction region 304.

The working gas 312 may be a single noble gas such as helium, neon, argon, krypton, or xenon. The working gas 312 may also be a mixture of a noble gas in combination with an inert gas such as nitrogen gas, hydrogen, helium, or any mixture thereof.

In step 508, a microwave source 334 is activated. The microwave source may operate at a frequency between 0.7 GHZ and 100 GHz at a power between 20 watts and 3000 watts. The microwave source 334 may provide microwave power in the form of rapidly alternating electric fields which can heat the substrate 308 which contains mobile electric charges, such as electrons and holes. Semiconducting and conducting samples heat in the presence of a microwave source 334 when charges within them are accelerated by the electric field and form an electric current. Those charges then lose the gained energy through collisions with the lattice atoms of the substrate 308 (resistive heating) and thereby heat the substrate 308. The microwave source 334 may provide additional heating to the energy to the top surface region 332 of the substrate 308 such that the temperature of the surface region 332 of the substrate 308 may, in combination with the plasma 328, which is discussed in step 510 provide the required activation energy for the PEA process.

For a PEA dopant activation and anneal process, the microwave source 334 may provide additional heating such that the temperature of the surface region 332 of the substrate 308 may be between 200° C. and 500° C., which may in combination with the plasma 328 which is discussed in step 510 provide the required activation energy in the top surface region 332 of the substrate 308 to activate the dopants and anneal crystalline damage to the substrate 308.

For a PEA silicide layer formation process of a cobalt metal layer, the microwave source 334 may provide additional heating such that the temperature of the surface region 332 of the substrate 308 may be between of between 200° C. and 600° C., which may in combination with the plasma 328 which is discussed in step 510 provide the required activation energy for the solid state reaction of cobalt and silicon in the substrate 308 to form a cobalt silicide layer.

For a PEA silicide formation process of a metal layer containing nickel, the microwave source 334 may provide additional heating such that the temperature of the surface region 332 of the substrate 308 may be between of between 100° C. and 250° C., which may in combination with the plasma 328 which is discussed in step 510 provide the required activation energy for the solid state reaction of nickel and silicon in the substrate 308 to form a nickel silicide layer.

For a high-k dielectric anneal PEA process, the microwave source 334 may provide additional heating such that the temperature of the surface region 332 of the substrate 308 may be between of between 200° C. and 400° C., which may in combination with the plasma 328 which is discussed in step 510 provide the required activation energy to anneal and recrystallize the high-k dielectric layer on the substrate 308.

A thermal source (not specifically shown) may be used in addition to the microwave source 334 to provide additional thermal budget to the PEA process. Examples of the thermal source may be at least one of resistive heating, lamps, lasers, or ultraviolet radiation.

In step 510, for a dopant activation and anneal PEA, a silicide formation PEA, a silicide anneal PEA, or a high-k dielectric layer PEA, an RF bias power of between 5 Watts and 5000 Watts (power density of 0.015 watts/cm² and 15.5 watts/cm²) and an RF voltage bias ranging between 5 Volts and 500 Volts may be applied in the PEA reaction region 304 to form a plasma 328, which may provide sufficient energy to anneal and activate dopants in the top surface region 332 of the substrate 308, or form silicides, anneal silicides, or anneal high-k dielectric materials on the top surface region 332 of the substrate 108. The addition of a plasma 328 to the heating provided by the wafer chuck 320 and the microwave source 334 may advantageously dramatically drop the temperature necessary to activate and anneal dopants in the top surface region 332 of the substrate 308, or form silicides, anneal silicides, or anneal high-k dielectric materials on the top surface region 332 of the substrate 308.

In step 512, during the dopant annealing process, the dopants in the substrate 308 are activated at the top surface region 332 of the substrate 308 by the bombarding of the top surface region 332 of the substrate 308 with ions and non-ionic atoms of the plasma 328. PEA processing is advantageous for dopant activation as the bombardment of the top surface region 332 with plasma ions and atoms provide a significant activation in the top 25 nm to 50 nm of the substrate 308 which significantly reduces diffusion of dopant species within the crystal lattice near the top surface region 332 which is advantageous in applications such as advanced CMOS with very shallow junctions. As implanted, the activation of dopants may be less than 10 percent. The PEA process may increase the dopant activation to greater than 50 percent or more. For example, a PEA process at 300° C. may reduce the sheet resistance of an arsenic doped wafer (arsenic with a dose of 1×10¹⁴ cm⁻² at 10 keV) from between 5000 ohms/sq and 10,000 ohms/sq to between 200 ohms/sq and 500 ohms/sq indicating activation of the arsenic dopant.

The anneal time may be between 15 seconds and 1800 seconds. During the PEA process, ions from the plasma 328 collide with the top surface region 332 of the substrate 308. During the ion bombardment of the top surface region 332, some of the momentum of the bombarding ions is transferred to the atoms in the top surface region 332 of the substrate 308, leading to enhanced surface mobility of atoms in the surface layers of the substrate 308 and healing of defects such as interstitial dislocations and non-crystalline chain defects and activating the dopants.

Variation of working gas 312 stoichiometry, RF bias power, RF bias voltage, and optional heating by the microwave source 334 within the parameters of step 512 may impact the characteristics of the bombarding ions of the plasma and may allow precise control of the annealing rate, surface uniformity and crystallinity of the surface layers of the substrate 308. To determine the ion density of the plasma, J-V curves via Langmuir probe theory with a DC substrate bias may be used. The J-V curves may be used to calculate the ion saturation current (Iᵢₒₙ), floating potential (V_{f}), and electron temperature (Tₑ).

The addition of hydrogen to a noble gas such as argon as the working gas 312 may enhance the ion density of the plasma 328 and enhance the effects of the PEA process allowing lower temperatures to be used than with a noble gas alone as the working gas 312. A working gas 312 of a noble gas such as argon which contains helium may result in a plasma 328 including less plasma damage to the substrate 308 due to the smaller atomic mass of He and increased argon ionization via the penning effect in which the metastable He* provides a mechanism to generate additional argon ions. The addition of helium to the plasma 328 may also result in improved crystalline characteristics at a given momentum of plasma ions with lower applied substrate bias and lower overall power budget. This results in the ability to activate and anneal the substrate 308 at lower temperatures than through thermal heating alone and may result in less movement of the dopant species to be annealed and activated. IV curves of the low temperature PEA process at 300° C. show comparable diode characteristics to a substrate annealed using a 800° C. RTA while a substrate using a thermal anneal at 300° C. does not undergo sufficient activation to form a diode. Additionally, Raman shift data before and after a PEA dopant activation and anneal process including additional heat from the microwave source 334 indicates a significant Si peak enhancement after the PEA process indicating significant recrystallization of the substrate 308 during the PEA activation and anneal process.

During a PEA silicide layer formation process including a microwave source 334, the metal layer on the substrate 308 is bombarded with ions and non-ionic atoms of the plasma. The silicide layer formation time may be between 15 seconds and 1800 seconds. During the ion bombardment of the metal layer on the substrate 308, some of the momentum of the bombarding ions is transferred to the surface atoms of the metal layer on the substrate 308, which imparts enough activation energy for a solid state reaction between the metal layer and the top surface region 332 of the substrate 308 forming a metal silicide layer in the top surface region 332. A cobalt silicide layer may be formed using a PEA process including a microwave source 334 with a top surface region 332 at a temperature of between 200° C. and 600° C. A silicide layer containing nickel may be formed using a PEA process including a microwave source 334 with a top surface region 332 at a temperature of between 100° C. and 250° C.

Variation of working gas 312 stoichiometry, RF bias power, RF bias voltage, and heating by the microwave source 334 may impact the characteristics of the bombarding ions of the plasma which may allow precise control of the silicide formation rate and silicide thickness. The addition of hydrogen to a noble gas such as argon as the working gas 312 may enhance the ion density of the plasma 328 and lead to an enhanced PEA process at lower temperatures than a noble gas alone as the working gas 312. The addition of helium to a working gas 312 of a noble gas such as argon may result in a plasma 328 with less plasma damage to the substrate 308 than a plasma 328 of the noble gas of argon alone due to the smaller atomic mass of helium and increased argon ionization via the penning effect in which the metastable He* provides a mechanism to generate additional argon ions.

During a PEA silicide layer anneal process including a microwave source 334, the silicide layer on the top surface region 332 of the substrate 308 is bombarded with ions and non-ionic atoms of the plasma. The silicide layer anneal time may be between 15 seconds and 1800 seconds. During the ion bombardment of the silicide layer on the substrate 308, some of the momentum of the bombarding ions is transferred to the surface atoms of the silicide layer on the substrate 308, which imparts enough activation energy for solid state reactions to occur in the metal silicide layer and between the metal silicide layer and silicon atoms in the top surface region 332 of the substrate 308 which may result in improved crystallinity, improved diffusion of substrate atoms into the silicide layer, grain growth, improved silicide morphology, and stress relaxation. A cobalt silicide layer may be annealed using a PEA process including a microwave source 334 at a temperature of between 300° C. and 700° C. A silicide layer containing nickel may be annealed using a PEA process including a microwave source 334 at a temperature of between 200° C. and 400° C.

Variation of working gas 312 stoichiometry, RF bias power, RF bias voltage, and optional heating by the microwave source 334 may impact the characteristics of the bombarding ions of the plasma which may allow precise control of the silicide anneal and resulting silicide characteristics. The addition of hydrogen to a noble gas such as argon as the working gas 312 may enhance the ion density of the plasma 328 and lead to an enhanced PEA process at lower temperatures than a noble gas alone as the working gas 312. The addition of helium to a noble gas such as argon as the working gas 312 may result in a plasma 328 with less plasma damage to the substrate 308 than a working gas 312 of argon alone due to the smaller atomic mass of helium and increased argon ionization via the penning effect in which the metastable He* provides a mechanism to generate additional argon ions.

During an PEA high-k dielectric layer anneal process including a microwave source 334, the high-k dielectric layer on the top surface region 332 of the substrate 308 is bombarded with ions and non-ionic atoms of the plasma. The high-k dielectric layer anneal time may be between 15 seconds and 1800 seconds. During the ion bombardment of the high-k dielectric layer on the substrate 308, some of the momentum of the bombarding ions is transferred to the surface atoms of the high-k dielectric layer on the top surface region 332 of the substrate 308, which imparts enough activation energy to anneal the high-k dielectric layer which may result structural densification in which volatile residue and residual impurities from high-k dielectric layer precursors may be driven out of the high-k dielectric layer, reordering and densification may occur, oxygen vacancies may be reduced, defect passivation may occur, stoichiometry may be improved, and mechanical stress relief may occur between the high-k dielectric layer and the top surface region 332 of the substrate 308.

Variation of working gas 312 stoichiometry, RF bias power, RF bias voltage, and optional heating by the microwave source 334 may impact the characteristics of the bombarding ions of the plasma which may allow precise control of the high-k dielectric layer anneal and resulting high-k dielectric layer characteristics. The addition of hydrogen to a noble gas such as argon as the working gas 312 may enhance the ion density of the plasma 328 and lead to an enhanced PEA process at lower temperatures than a noble gas alone as the working gas 312. The addition of helium to a working gas 312 such as argon may result in a plasma 328 with less plasma damage to the substrate 308 due to the smaller atomic mass of helium and increased argon ionization via the penning effect in which the metastable He* provides a mechanism to generate additional argon ions.

In step 514, after the PEA process is complete, the plasma 328 and heating from the microwave source 334 are removed, the substrate 308 is allowed to cool, and the substrate 308 after the PEA process is removed from the containment chamber 302 via the wafer handling port 330.

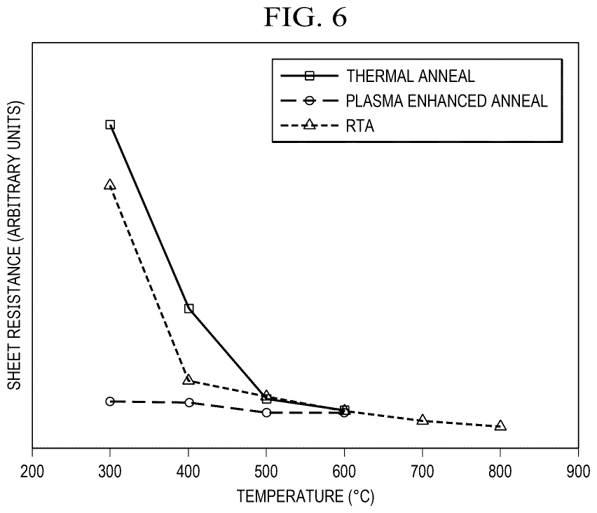

FIG. 6 is a graph showing the sheet resistance data of a substrate activated and annealed at various temperatures via a PEA process, a thermal process, and a RTA process. The thermal process is a 30 minute process, the RTA process is a 30 second process, and the PEA process includes an argon plasma at a pressure between 10 millitorr and 100 millitorr. The substrate was implanted with BF₂ with a dose of 1×10¹⁴ cm⁻² and an energy of 1 keV. As shown in the figure, the PEA process shows a significant data shows significant activation of the substrate at a temperature of 300° C. By contrast, the Rs of the thermal anneal is significantly higher at 300° C. than the PEA process indicating little or no activation for the thermal process at 300° C., and does not match the Rs of the PEA process until the thermal anneal is conducted at 600° C. The Rs of the RTA process is also significantly higher at 300° C. compared to the PEA process indicating little or no activation at 300° C. for the RTA process and does not match the Rs of the PEA process until also does not match the Rs of the PEA process until the RTA process is conducted at 600° C.

While various embodiments of the present disclosure have been described above, it should be understood that they have been presented by way of example only and not limitation. Numerous changes to the disclosed embodiments can be made in accordance with the disclosure herein without departing from the spirit or scope of the disclosure. Thus, the breadth and scope of the present invention should not be limited by any of the above described embodiments. Rather, the scope of the disclosure should be defined in accordance with the following claims and their equivalents.

What is claimed is:

1. A method forming a microelectronic device, comprising:
implanting a dopant into a top surface region of a substrate;
placing the substrate on a wafer chuck in a reaction chamber;
introducing a working gas into the reaction chamber and maintaining an ambient gas environment in the reaction chamber at a pressure between 0.1 millitorr and 200 torr;
heating the top surface region of the substrate to a temperature between 200° C. and 500° C.;
exposing the top surface region of the substrate to a plasma with a voltage bias ranging from 5 volts to 500 volts, a power density ranging from 0.015 watts/cm² to 15.5 watts/cm², and a time between 15 seconds and 1800 seconds, wherein the dopant is greater than 50 percent activated;
cooling the substrate; and
removing the substrate from the reaction chamber.

2. The method of claim 1, wherein the working gas includes a gas selected from the group consisting of helium, neon, argon, krypton, xenon, and nitrogen.

3. The method of claim 2, wherein the working gas includes hydrogen.

4. The method of claim 1, wherein the substrate is heated by at least one source selected from the group consisting of resistive heating, microwaves with a frequency of a microwave source between 0.7 GHz and 100 GHz, lamps, lasers, and ultraviolet radiation.

5. The method of claim 1, wherein the substrate is doped by at least one element selected from the group consisting of arsenic, boron, phosphorous, antimony, selenium, tellurium, gallium, indium, and aluminum.

6. A method forming a microelectronic device, comprising:
forming a metal layer on a top surface region of a substrate;
placing the substrate on a wafer chuck in a reaction chamber;
introducing a working gas into the reaction chamber and maintaining an ambient gas environment in the reaction chamber at a pressure between 0.1 millitorr and 200 torr; heating the substrate to a formation temperature;
exposing the top surface region of the substrate to a plasma with a voltage bias ranging from 5 volts to 500 volts, a power density ranging from 0.015 watts/cm² to 15.5 watts/cm², and a time between 15 seconds and 1800 seconds, wherein the metal layer and a top surface region of the substrate undergo a chemical transformation forming a metal silicide layer;
cooling the substrate;
removing the substrate from the reaction chamber; and
removing an unreacted metal from the substrate.

7. The method of claim 6, wherein the working gas includes a gas selected from the group consisting of helium, neon, argon, krypton, xenon, and nitrogen.

8. The method of claim 7, wherein the working gas includes hydrogen.

9. The method of claim 6, wherein the substrate is heated by a source selected from at least one of the group consisting of resistive heating, microwaves with a frequency of a microwave source between 0.7 GHZ and 100 GHz, lamps, lasers, and ultraviolet radiation.

10. The method of claim 6, wherein the metal layer is one of the group consisting of titanium, cobalt, tungsten, manganese, iron, copper, vanadium, zirconium, hafnium, and thorium, and the formation temperature is between 200° C. and 600° C.

11. The method of claim 6, wherein the metal layer contains nickel and the formation temperature is between 100° C. and 250° C.

12. A method forming a microelectronic device, comprising:
placing a substrate including a metal silicide layer on a top surface region which has been formed and unreacted metal has been stripped off, on a wafer chuck in a reaction chamber;
introducing a working gas into the reaction chamber and maintaining an ambient gas environment in the reaction chamber at a pressure of between 0.1 millitorr and 200 torr;
heating the substrate to an annealing temperature;
exposing a top surface region of the substrate to a plasma with a voltage bias ranging from 5 volts to 500 volts, a power density ranging from 0.015 watts/cm² to 15.5 watts/cm², and a time between 15 seconds and 1800 seconds wherein a metal silicide layer on the substrate is annealed and undergoes stress relaxation and grain growth;
cooling the substrate; and
removing the substrate from the reaction chamber.

13. The method of claim 12, wherein the working gas includes a gas selected from the group consisting of helium, neon, argon, krypton, xenon, and nitrogen.

14. The method of claim 13, wherein the working gas includes hydrogen.

15. The method of claim 12, wherein the substrate is heated by a source selected from at least one of the group consisting of resistive heating, microwaves with a frequency of a microwave source between 0.7 GHZ and 100 GHz, lamps, lasers, and ultraviolet radiation.

16. The method of claim 12, wherein the metal silicide layer is one of the group consisting of titanium silicide, cobalt silicide, tungsten silicide, manganese silicide, iron silicide, copper silicide, vanadium silicide, zirconium silicide, hafnium silicide, and thorium silicide, and the annealing temperature is between 300° C. and 700° C.

17. The method of claim 12, wherein the metal silicide layer contains nickel and the annealing temperature is between 200° C. and 400° C.

18. A method forming a microelectronic device, comprising:
forming a high-k dielectric layer on a top surface region of a substrate;
placing the substrate on a wafer chuck in a reaction chamber;
introducing a working gas into the reaction chamber and maintaining an ambient gas environment in the reaction chamber at a pressure between 0.1 millitorr and 200 torr; heating the top surface region of the substrate to a temperature between 200° C. and 400° C.;
exposing the top surface region of the substrate to a plasma with a voltage bias ranging from 5 volts to 500 volts, a power density ranging from 0.015 watts/cm² to 15.5 watts/cm², and a time between 15 seconds and 1800 seconds wherein volatile residue is reduced, oxygen vacancies are reduced, and mechanical stress between the high-k dielectric layer and the top surface region of the substrate is reduced;
cooling the substrate; and
removing the substrate from the reaction chamber.

19. The method of claim 18, wherein the working gas includes a gas selected from the group consisting of helium, neon, argon, krypton, xenon, and nitrogen.

20. The method of claim 19, wherein the working gas includes hydrogen.

21. The method of claim 18, wherein the substrate is heated by a source selected from at least one of the group consisting of resistive heating, microwaves with a frequency of a microwave source between 0.7 GHZ and 100 GHz, lamps, lasers, and ultraviolet radiation.

22. The method claim 18, wherein the high-k dielectric layer on the top surface region of the substrate is selected from the group consisting of SiₓO_{y}, SiₓN_{y}, HfOₓ, HfₓSiO_{y}, ZrOₓ, ZrₓSiO_{y}, LaₓGdO_{y}, SiOₓ, SiNₓ, SiOₓN_{y}, and TaOₓ.
